(19) United States
(12) Patent Application Publication
(10) Pub. No.: US 2009/0183984 A1
(43) Pub. Date: Jul. 23, 2009

(54) Seed Film Forming Method, Plasma-Assisted Film Forming System and Storage Medium

(76) Inventors: Takashi Sakuma, Yamanashi-Ken (JP); Taro Ikeda, Yamanashi-Ken (JP); Osamu Yokoyama, Yamanashi-Ken (JP); Tsukasa Matsuda, Albany, NY (US); Tatsuo Hatano, Yamanashi-Ken (JP); Yasushi Mizusawa, Albany, NY (US)

Correspondence Address: SMITH, GAMBRELL & RUSSELL, 1130 CONNECTICUT AVENUE, N.W., SUITE 1130, WASHINGTON, DC, 20036, US

(21) Appl. No.: 12/223,383

(22) PCT Filed: Jan. 26, 2007
(86) PCT No.: PCT/JP2007/051293

§ 371 Date: Dec. 11, 2008

(30) Foreign Application Priority Data
Jan. 31, 2006 (JP) 2006-022239

(51) Int. Cl. C23C 14/34; C23C 14/14

(52) U.S. Cl. 204/192.15; 204/192.12; 204/298.08

(57) ABSTRACT

The invention is related to A seed film forming method capable of forming a seed film in recesses without forming overhangs.

The seed film forming method of depositing a seed film for plating includes the steps of: producing metal ions by ionizing a metal target with a plasma in a processing vessel that can be evacuated; and depositing a metal film on a surface provided with recesses of a workpiece mounted on a stage placed in the processing vessel by supplying bias power to the workpiece to attract the metal ions to the workpiece; wherein a film deposition step of depositing the metal film by using the bias power determined so that the metal film deposited on the surface of the workpiece may not be sputtered, and a film deposition interrupting step of interrupting the deposition of the metal film by stopping producing the metal ions are repeated alternately by a number of cycles.

### TECHNICAL FIELD

The present invention relates to a seed film forming method and a plasma-assisted film forming system and, more particularly, to a seed film forming method of forming a seed film to fill up a recess formed in a workpiece, such as a semiconductor wafer, a plasma-assisted film forming system and a storage medium.

### BACKGROUND ART

Generally, a semiconductor wafer is subjected repeatedly to processes including a film forming process and pattern-forming etching process to build desired semiconductor devices on the semiconductor wafer. Width of lines and diameters of holes formed on a semiconductor wafer have been progressively reduced to meet demand for further increasing the scale of integration and further device miniaturization. There is a tendency to use copper as a wiring material and a filling material because device miniaturization requires the reduction of electric resistance, and copper is inexpensive and has very low electric resistance (Patent documents 1, 2 and 3). When copper is used as a wiring material or a filling material, a film of tantalum (Ta) or tantalum nitride (TaN) is deposited as a barrier layer to ensure the close adhesion of a copper wiring line or a copper filler to the underlying layer.

When a recess formed in a wafer needs to be filled up, a thin seed film of copper is formed over the entire surface of the wafer including side surfaces of the recess by a plasma sputtering system, and then the entire surface of the wafer is coated with a thin copper film by a copper-plating process so as to fill up the recess completely. Subsequently, excess parts of the thin copper film are removed by CMP (chemical/mechanical polishing).

These processes will be described with reference to FIGS. 9 to 11. FIG. 9 is a sectional perspective view of a semiconductor wafer provided with a recess formed in its surface, FIG. 10 is a sectional view of assistance in explaining steps of a known film forming method of partly filling up the recess shown in FIG. 9, and FIG. 11 is a sectional view of assistance in explaining a process of overhang formation. As shown in FIG. 9, a long recess 2 having a rectangular cross section, namely, a trench, is formed in an insulating layer 3 formed on a surface of a semiconductor wafer W, and a hole-shaped recess 4, such as a via or a through hole, is formed in the bottom of the trench-shaped recess 2. Thus the recesses are formed in two steps. A wiring layer 6, namely, an underlayer, underlies the hole-shaped recess 4. The recess 4 is filled up with an electrically conductive material to interconnect metal layers. This two-step structure is called a dual damascene structure. In some cases, the trench-shaped recess 2 or the hole-shaped recess 4 is formed individually. The continued shrinkage of design rule requires forming the recess 2 in a very small width and forming the recess 4 in a very small diameter. Accordingly, the aspect ratio, namely, the width-to-depth ratio, of a recess to be filled up increased to a value between about three and about four.

A method of filling the recess 4 having the shape of a via hole with a filling material will be described with reference to FIG. 10. As shown in FIG. 10(A), a uniform barrier layer 8, namely, a two-layer base film of a TaN film and a Ta film, is formed on, a surface of a semiconductor wafer W including surfaces of the recess 4 by a plasma sputtering system. As shown in FIG. 10(B), the surface of the semiconductor wafer W including surfaces of the recess 4 is coated with a metal seed film 10, i.e., a thin copper film, by the plasma sputtering system. When the seed film 10 is formed by the plasma sputtering system, a high-frequency voltage bias power is supplied to the semiconductor wafer W to attract copper ions efficiently to the semiconductor wafer W. The surface of the wafer W is processed by three-dimensional copper plating (3D copper plating) to fill up the recess 4 with, for example, a metal film 12 of copper. The upper trench-shaped recess 2 also is filled up with copper by copper plating. Subsequently, excess parts of the metal film 12, the seed film 10 and the barrier layer 8 are removed by a CMP process or the like.
Patent document 1: JP 2000-77365 A
Patent document 2: JP 10-74760 A
Patent document 3: JP 10-214836 A

### DISCLOSURE OF THE INVENTION

### Problem to be Solved by the Invention

As mentioned above, the plasma sputtering system promotes the attraction of metal ions to the semiconductor wafer by supplying bias power to the semiconductor wafer to deposit a film at a high deposition rate. If an excessively high bias voltage is applied to the semiconductor wafer, the surface of the wafer is sputtered with ions of an inert gas serving as a plasma excitation gas, such as argon gas. Consequently, the previously deposited metal film is removed. Therefore, the bias power is not very high.

When the seed film 10 of copper is deposited on the wafer, parts of the seed film 10 deposited around the edges of the open upper end of the recess 4 protrude in overhangs 14 and narrows the open upper end as shown in FIG. 10(B). When such a wafer is subjected to a plating process to fill up the recess 4 with the metal film 12 of copper, a plating bath cannot enter the recess 4 satisfactorily, the recess 4 cannot be filled completely with the metal film 12 and, in some cases, a void is formed in the metal film 10.

A process of formation. of the overhangs 14 will be described with reference to FIG. 11. Metal particles, namely, Cu particles, sputtered by a plasma sputtering process contain neutral particles in addition to metal ions ionized by a plasma. Whereas the metal ions are caused to travel directionally by the bias power and fall substantially perpendicularly on the surface of the wafer, the neutral metal particles fall on the surface of the wafer from all directions. There is a tendency for neutral metal particles C1 obliquely traveling toward the wafer to deposit intensively on edge parts of the open upper end of the recess 4.

When the metal film deposited on the edge parts of the open upper end of the recess is bombarded by the metal particles and metal ions C2, sometimes, metal particles C3 are sputtered from the metal film deposited on the edge parts and the metal particles C3 sputtered from the metal film on one of the edge parts adhere again to the metal film on the opposite edge part.

Even though the wafer is cooled during the deposition of the seed film to control surface diffusion in the metal film, surface diffusion occurs unavoidably to some extent. Consequently, metal particles move in the surface of the metal film due to surface diffusion. The metal film coating the edge parts tends to mass in a spherical shape to reduce the surface area during surface diffusion and, consequently, parts of the seed film coating the edge parts bulge out in a curved shape. Thus the overhangs 14 are formed.

A void 16 is liable to be formed if the overhangs 14 are formed. To prevent the formation of the void 16, various additives are added to the plating bath for copper plating to raise the bottom of the recess 4 by promoting the deposition of the copper film so that the copper film is deposited as much as possible in the bottom of the recess 4.

Those additives remain slightly in the metal film of copper. Those additives could be removed from the metal film by subjecting the metal film to a high-temperature annealing process after the plating process and wiring lines of a metal film of pure copper could be formed.

Continued reduction of line width and hole diameter in recent years requires line width and hole diameter of 100 nm or below. Under such a condition, the additives that could have been easily removed from the metal film of copper by the high-temperature annealing process cannot be satisfactorily removed from the metal film of copper and some of the additives remain in the metal film.

The additives contained in the metal film of copper increase the resistance of wiring lines formed by processing the metal film, a metal film having design electrical characteristics cannot be formed. The residual additives suppress the growth of copper grains during the annealing process and reduce the reliability of the metal film.

To avoid troubles caused by the additives, studies have been made to fill up the recess 4 by a plasma sputtering process instead of by the plating process. However, as mentioned above in connection with FIG. 10(B), the overhangs 14 formed on the edge parts of the open upper end of the recess 4 obstruct the travel of metal ions to the depth of the recess 4. Consequently, the void 16 is formed inevitably.

As mentioned in Patent documents 2 and 3, the recess 4 may be filled up with the metal film by causing the reflow of the deposited metal film by subjecting the metal film to a high-temperature process to solve problems resulting from the overhangs 14. Although the problems may be solved if the metal film is formed of aluminum that melts very easily, the metal film of copper is hard to melt and is hard to cause to reflow. Thus the methods mentioned in Patent document 2 and 3 are practically inapplicable measures for solving those problems.

The present invention has been made to solve those problems effectively. Accordingly, it is an object of the present invention to provide a seed film forming method capable of forming a seed film without forming overhangs, a plasma film forming system and a storage medium.

### Means for Solving the Problem

A seed film forming method of depositing a seed film for plating in a first aspect of the present invention includes the steps of: producing metal ions by ionizing a metal target with a plasma in a processing vessel that can be evacuated; and depositing a metal film on a surface provided with recesses of a workpiece mounted on a stage placed in the processing vessel by supplying bias power to the workpiece to attract the metal ions to the workpiece; wherein a film deposition step of depositing the metal film by using the bias power determined so that the metal film deposited on the surface of the workpiece may not be sputtered, and a film deposition interrupting step of interrupting the deposition of the metal film by stopping producing the metal ions are repeated alternately by a number of cycles.

Thus the film deposition step of depositing the metal film using the bias power that does not cause the deposited metal film to be sputtered and the film deposition interrupting step for interrupting producing the metal ions to interrupt the deposition of the metal film are repeated alternately by a number of cycles. Therefore, the metal film deposited on the surface of the workpiece is not sputtered off. Since the deposition of the metal film is interrupted intermittently, surface diffusion of the metal particles in the metal film can be controlled. Thus the seed film can be formed without forming overhangs and therefore the recesses can be filled up with a metal by a plating process without forming any void.

In the seed film forming method, the film deposition step sets the interior of the processing vessel at a pressure not lower than a predetermined pressure to produce the metal ions at an ionization rate not lower than a predetermined ionization rate.

Metal ions can be produced at an ionization rate not lower than a predetermined ionization rate by setting the interior of the processing vessel at a pressure not lower than a predetermined pressure. Thus the production of neural metal particles, which are one of factors causing the formation of overhangs, can be controlled and hence the formation of overhangs can be suppressed accordingly.

For example, the predetermined ionization rate is 80%.

For example, the predetermined pressure is 50 mTorr.

For example, the supply of plasma generating power for generating the plasma and the supply of discharging power supplied to the target are stopped during the film deposition interrupting step.

For example, the supply of the bias power to the workpiece is stopped during the film deposition interrupting step.

For example, the workpiece is cooled throughout the film deposition step and the film deposition interrupting step.

For example, the duration of one cycle of the film deposition step is 10 sec or below.

For example, the seed film has an overall thickness of 100 nm or below.

For example, the bias power is 0.3 W/cm² or below

For example, the recess has a width or a diameter of 150 nm or below.

For example, the metal film is formed of copper, ruthenium (Ru), a copper alloy or a ruthenium alloy.

A plasma-assisted film forming system in a second aspect of the present invention for depositing a metal film as a seed film for plating on the surface of a workpiece and in recesses in the workpiece by attracting metal ions by the agency of bias power includes: a processing vessel capable of being evacuated; a stage for supporting thereon a workpiece having a surface provided with recesses;

a gas supply means for supplying predetermined gases into the processing vessel; a plasma generator for generating a plasma in the processing vessel; a metal target placed in the processing vessel so as to be ionized by the plasma; a dc power supply for supplying discharge power to the metal target; a bias power supply for supplying bias power to the stage; and a system controller for controlling operations of the plasma-assisted film forming system; wherein the system controller executes control operations so that a film deposition step using the bias power adjusted such that the metal film deposited on the surface of the workpiece is not sputtered, and a film deposition interrupting step of interrupting the deposition of the metal film by stopping producing metal ions are repeated alternately by a number of cycles.

For example, the stage is provided with a cooling means for cooling the workpiece;

For example, the stage is provided in its surface with gas grooves through which a heat-transfer gas flows.

A storage medium in a third aspect of the present invention stores a control program for controlling film deposition operations of a plasma-assisted film forming system, for depositing a metal film as a seed film for plating on the surface of a workpiece and in recesses in the workpiece by attracting metal ions by the agency of bias power, the plasma-assisted film forming system, including: a processing vessel capable of being evacuated, a stage for supporting thereon a workpiece having a surface provided with recesses, a gas supply means for supplying predetermined gases into the processing vessel, a plasma generator for generating a plasma in the processing vessel, a metal target placed in the processing vessel so as to be ionized by the plasma, a dc power supply for supplying discharge power to the metal target, a bias power supply for supplying bias power to the stage, and a system controller for controlling operations of the plasma-assisted film forming system, such that the system controller controls the plasma-assisted film forming system so that a film deposition step using the bias power adjusted so that the metal film deposited on the surface of the workpiece may not be sputtered, and a film deposition interrupting step of interrupting the deposition of the metal film by stopping producing the metal ions are repeated alternately by a number of cycles.

The seed film forming method, the plasma-assisted film forming system and the storage medium according to the present invention demonstrate the following excellent effects.

The seed film is deposited by alternately repeating the film deposition step using the bias power adjusted so that the metal film deposited on the surface of the workpiece may not be sputtered, and the film deposition interrupting step of interrupting the deposition of the metal film by stopping producing the metal ions by a number of cycles. Therefore, the metal film deposited on the surface of the workpiece is not sputtered again. Since film deposition is interrupted intermittently, the movement of the deposited metal film resulting from surface diffusion, which occurs during a continuous sputtering process, can be suppressed and hence the seed film can be formed without forming overhangs.

Since the seed film can be formed without forming overhangs, the recesses can be filled up without forming voids by a subsequent plating process.

Metal ions can be generated at an ionization rate not lower than a predetermined ionization rate by keeping a pressure not lower than a predetermined pressure in the processing vessel. Consequently, the existence neutral metal particles can be suppressed and hence the formation of overhangs can be suppressed accordingly.

### BRIEF DESCRIPTION OF THE DRAWINGS

FIG. 1 is a sectional view of a plasma-assisted film forming system according to the present invention;

FIG. 2 is a graph of assistance in explaining the dependence of sputter etching on angle;

FIG. 3 is a graph showing the relation between deposition rate and bias power;

FIG. 4 is a flow chart of a film forming method according to the present invention;

FIG. 5 is a time chart of assistance in explaining the film forming method according to the present invention;

FIG. 6 is a sectional view of assistance in explaining a seed film deposited by the film forming method according to the present invention;

FIGS. 7(A) and 7(B) are microphotographs of holes in which seed films were formed by a method according to the present invention and a known method, respectively, taken by an electron photomicroscope;

FIGS. 8(A) and 8(B) are microphotographs of trenches in which seed films were formed by a method according to the present invention and a known method, respectively, taken by an electron photomicroscope;

FIG. 9 is a perspective view of an example of a recess formed in a surface of a semiconductor wafer, showing a cross section;

FIGS. 10(A), 10(B) and 10(C) are sectional views of assistance in explaining a known film forming method of filling up the recess shown in FIG. 9; and

FIG. 11 is a sectional view of assistance in explaining a process of overhang formation.

### BEST MODE FOR CARRYING OUT THE INVENTION

A seed film forming method, a plasma-assisted film forming system and a storage medium in preferred embodiments according to the present invention will be described with reference to the accompanying drawings.

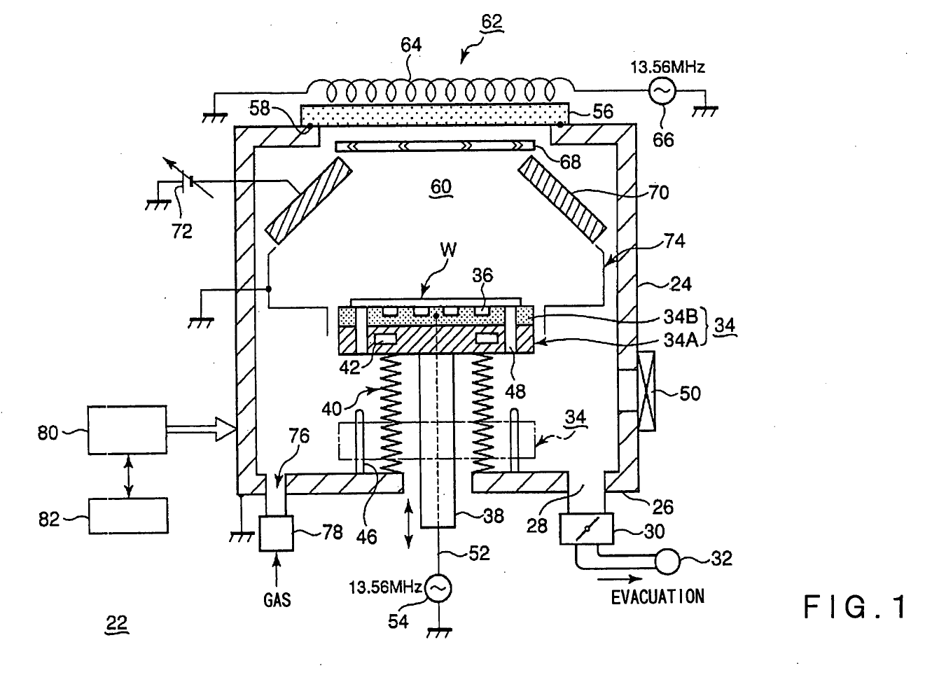

FIG. 1 is a sectional view of a plasma-assisted film forming system according to the present invention. The plasma-assisted film forming system is an ICP (inductively coupled plasma) sputtering system. Referring to FIG. 1, a plasma-assisted film forming system 22 includes a cylindrical processing vessel 24 made of aluminum or such. The processing vessel 24 is grounded. The processing vessel 24 has a bottom wall 26 provided with an exhaust port 28. The processing vessel 24 can be evacuated through a throttle valve capable of pressure regulation by a vacuum pump 32.

A disk-shaped stage 34 made of, for example, aluminum is installed in the processing vessel 24. The stage 34 has a body 34A and an electrostatic chuck 34B mounted on the body 34A. A semiconductor wafer W, namely, a workpiece, mounted on the electrostatic chuck 34B is attracted to and held on the electrostatic chuck 34B. The electrostatic chuck 34B is provided in its upper surface with grooves 36 for a heat-transfer gas. When necessary, a heat-transfer gas, such as Ar gas is passed through the grooves 36 to enhance thermal conduction between the wafer W and the stage 34. When necessary, a dc voltage is applied to the electrostatic chuck 34B to attract the wafer W to the electrostatic chuck 34B. A support rod 38 is connected to a central part of the lower surface of the stage 34 to support the stage 34 thereon. A lower part of the support rod 38 extends through the bottom wall 26 of the processing vessel 24. The support rod 38 is moved vertically by a lifting mechanism, not shown, to move the stage 34 vertically.

An expandable metal bellows 40 surrounds the support rod 38. The metal bellows 40 has an upper end joined to the lower surface of the stage 34 in an airtight fashion and a lower end joined to the inside surface of the bottom wall 26 in an airtight fashion. The stage 34 can be vertically moved, while the processing vessel 24 is kept in an airtight condition. The body 34A of the stage 34 is provided with a coolant circulating passage 42, namely, a cooling. means. A coolant is circulated through the coolant circulating passage 42 to cool the wafer W. The coolant is supplied into and discharged from the coolant circulating passage 42 through passages, not shown, formed in the support rod 38.

Three support pins 46 (only two of them are shown in FIG. 1) are set upright on the bottom wall 26. The stage 34 is provided with through holes 48 for receiving the support pins 46 so as to correspond to the support pins 46, respectively. When the stage 34 is lowered, the support pins 47 are received in the through holes 48, and upper end parts of the support pins 46 project upward from the stage 34 to support the wafer W thereon. Thus the wafer W can be transferred between the support pins 46 and an external carrying arm, not shown, moved into the -processing vessel 24. The carrying arm can enter the processing vessel 24 through a gate valve 50 attached to a lower part of the side wall of the processing vessel 24.

A bias power supply 54, namely, a high-frequency power supply capable of generating a high-frequency wave of, for example, 13.56 MHz, is connected to the electrostatic chuck 34B mounted on the body 34A by a wiring line 52 to supply bias power to the stage 34. The bias power provided by the bias power supply 54 can be controlled as the need arises.

A transmission plate 56 transparent to high-frequency waves is joined hermetically through a sealing member 58, such as an O ring, to the top wall of the processing vessel 24. The transmission plate 56 is made of a dielectric material, such as aluminum oxide. A plasma generator 62 is mounted on the transmission plate 56 to generate a plasma by ionizing a plasma excitation gas, such as Ar gas, in a processing space 60 defined by the processing vessel 24. The plasma excitation gas may be an inert gas other than Ar gas, such as He gas or Ne gas. More concretely, the plasma generator 62 includes an induction coil 64 disposed so as to correspond to the transmission plate 56 and connected to a high-frequency power supply 66 to generate a plasma generating high-frequency wave of, for example, 13.56 MHz. A high-frequency wave is propagated through the transmission plate 56 into the processing space 60. The output of the high-frequency power supply 66, namely plasma generating power, can be controlled as the need arises.

A baffle plate 68 made of, for example, aluminum for diffusing the high-frequency wave propagated into the processing space 60 is disposed right below the transmission plate 56. A metal target 70 is disposed below the baffle plate 68 so as to surround an upper part of the processing space 60. The metal target 70 has the shape of shell resembling an upward tapered, truncated circular cone. A variable dc power supply 72 is connected to the metal target 70 to supply discharging power to the metal target 70. Thus output dc power of the variable dc power supply 72, namely discharging power, can be controlled as the need arises. The metal target 70 is made of tantalum or copper or the like. The metal target 70 are sputtered in the form of atomes and atomic groups of the metal by Ar ions. Most of the atoms and the atomic groups of metal are ionized during passage through the plasma. A tantalum target is used for forming a barrier layer, and a copper target is used for forming a seed film by the film forming method of the present invention.

The processing space 60 is surrounded by a cylindrical protective cover 74 made of, for example, aluminum and disposed below the metal target 70. The protective cover 74 is grounded. A lower part of the protective cover 74 is bent inward so that the inner edge thereof is close to the side surface of the stage 34. The bottom wall of the processing vessel 24 is provided with a gas supply port 76, namely, a gas supply means. Predetermined, necessary gases are supplied through the gas supply port 76 into the processing vessel 24. Plasma excitation gases, such as Ar gas and a necessary gas, such as nitrogen gas, are supplied through a gas controller 78 including flow regulators and valves.

The components of the film forming system 22 are controlled by a system controller 80, such as a computer, connected thereto. The system controller 80 controls operations of the bias power supply 54, the plasma-generating high-frequency power supply 66 to generate a plasma, the variable dc power supply 72, the gas controller 78, the throttle valve 30 and the vacuum pump 32 to deposit a metal film by the film forming method of the present invention. The system controller 80 carries out the following control operations.

The vacuum pump 32 operates under the control of the system controller 80 to evacuate the processing vessel 24, Ar gas is supplied into the evacuated processing vessel 24 under the control of the gas controller 78, and the throttle valve is controlled to maintain the interior of the processing vessel 24 at a predetermined vacuum. Then, the variable dc power supply 72 supplies dc power to the metal target 70, and the high-frequency power supply 66 supplies high-frequency power (plasma generating power) to the induction coil 64.

The system controller 80 makes the bias power supply 54 supply predetermined bias power to the stage 34. Consequently, argon plasma containing argon ions is generated in the processing vessel 24 by the agency of the dc power supplied to the metal target 70 and the plasma generating power supplied to the induction coil 64. The argon ions impacted on the metal target 70 make the metal target 70 sputter thereby release the metal particles.

Most of the metal atoms, ejected by sputtering from the metal target 70 are ionized during travel through the plasma. Consequently, a mixture of metal ions, namely, the ionized metal atoms, and electrically neutral metal atoms flies downward as metal particles. The metal ions, in particular, are attracted highly directionally by the bias power supplied to the stage 34 and deposit on the wafer W held on the stage 34.

In a process of depositing a seed film for plating, the system controller 80 can deposit a metal film (Cu film) such that the Cu film once deposited on the surface of the wafer W may not be sputtered by limiting the output of, for example, the bias power supply 54. The system controller 80 controls the component parts of the plasma-assisted film forming system on the basis of a program designed to deposit a meal film under predetermined conditions. The program including a set of instructions for the system controller 80 to control the component parts is stored in a storage medium 82, such as a floppy disk® (FD), a compact disk® (CD) or a flash memory. The system controller 80 controls the component parts on the basis of the program stored in the storage medium 82 to achieve processes under predetermined conditions.

A seed film forming method to be carried out by the plasma-assisted film forming system 22 will be described.

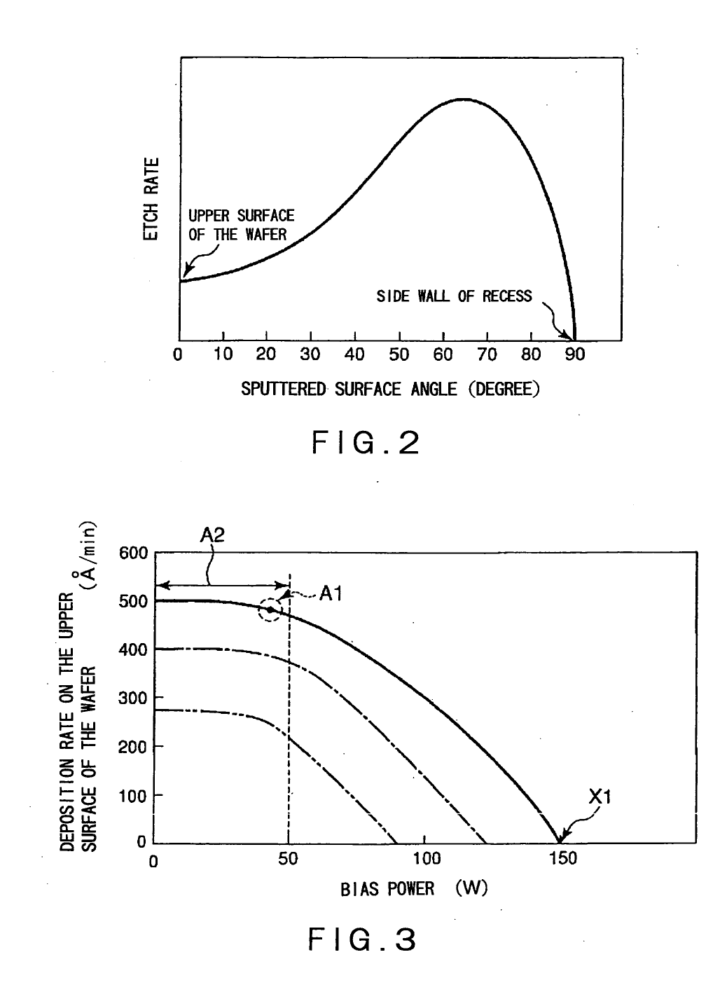

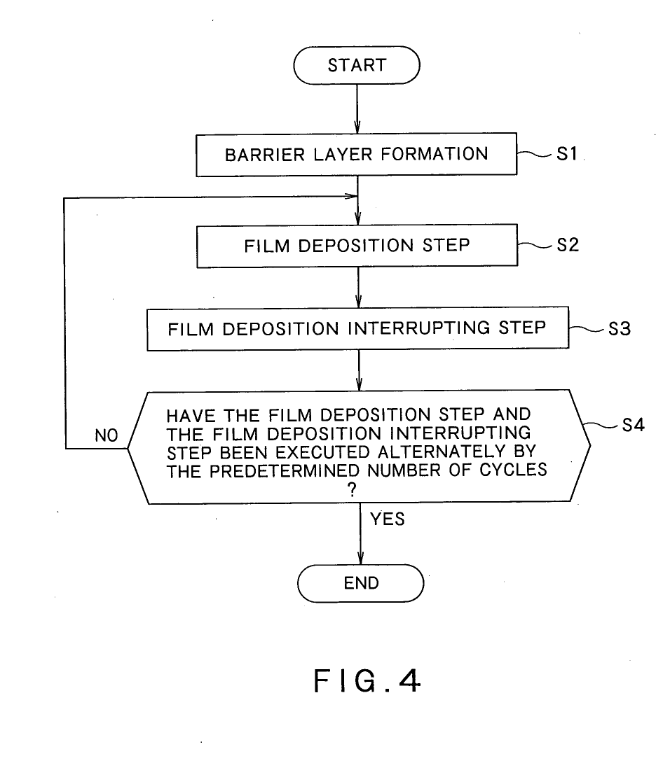

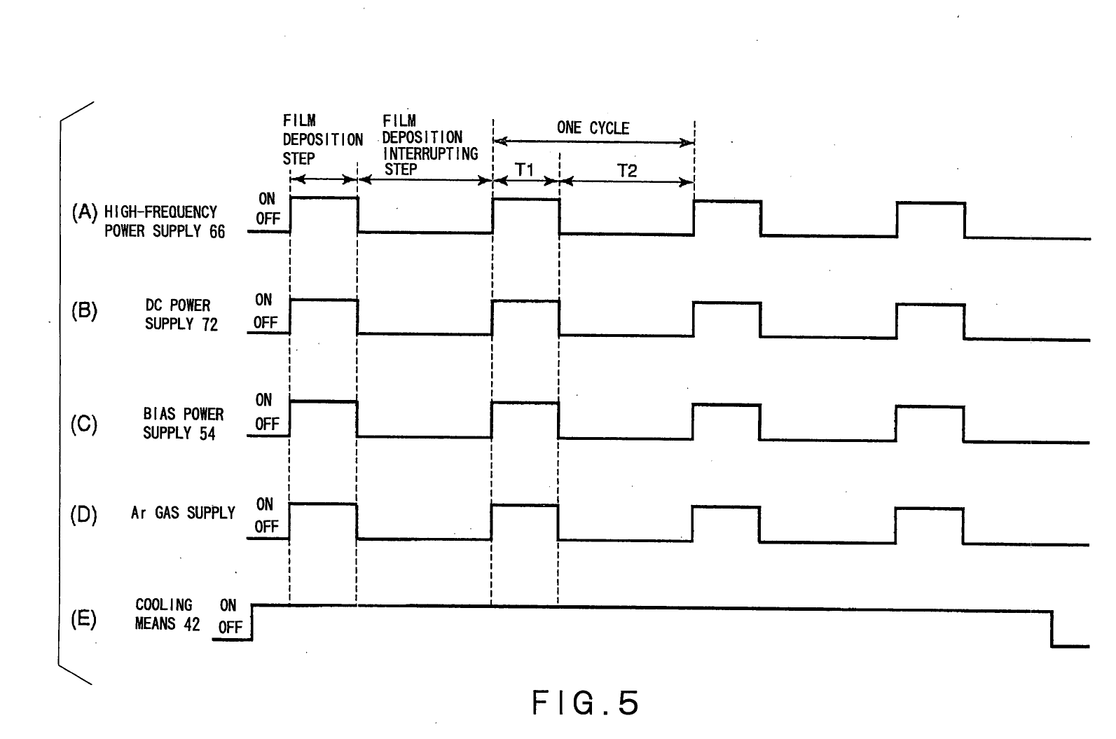

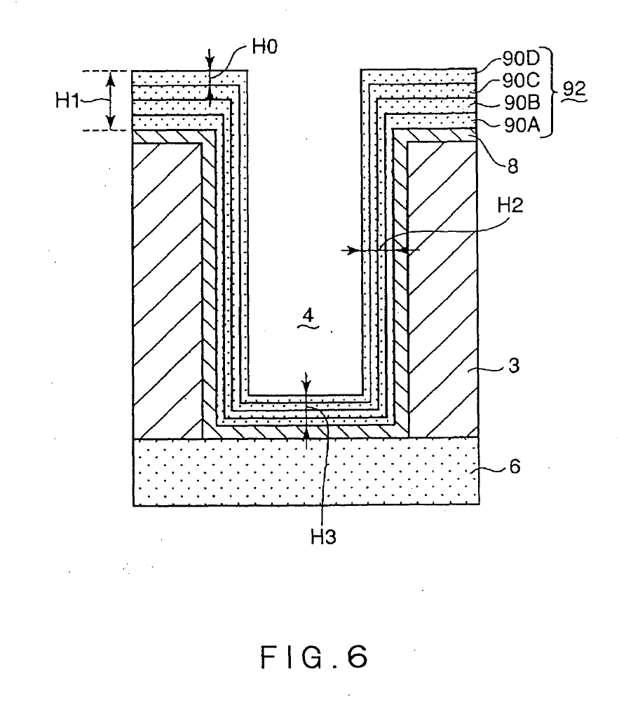

FIG. 2 is a graph of assistance in explaining the dependence of sputter etching on angle, FIG. 3 is a graph showing the relation between deposition rate and bias power, FIG. 4 is a flow chart of a film forming method according to the present invention, FIG. 5 is a time chart of assistance in explaining the film forming method according to the present invention, and FIG. 6 is a sectional view of assistance in explaining a seed film deposited by the film forming method according to the present invention.

The film forming method of the present invention is featured by a film deposition step of depositing a metal film on a surface of a semiconductor wafer by supplying bias power determined so that a metal film once deposited on the surface of the semiconductor wafer may not be sputtered, and alternately repeating a film deposition step of forming the metal film and a film deposition interrupting step of interrupting the deposition of the metal film by stopping producing the metal ions by a number of cycles.

The film deposition step forms a metal film by sputtering using a plasma. The bias power, the dc power and the plasma generating power are controlled properly so that a metal film once deposited on the upper surface of the wafer may not be sputtered by the plasma containing Ar ions. More concretely, the bias power is determined such that metal ions are attracted to the upper surface of the wafer (FIG. 1) so as to deposited a film at a film deposition rate and the film is sputter-etched by the plasma (Ar⁺ ions) at an etch rate substantially equal to zero

This will be more specifically described.

The characteristic of etch rate during sputter-etching using the plasma will be examined without giving consideration to deposition rate. The relation between sputtered surface angle and etch rate is illustrated by the graph shown in FIG. 2. The sputtered surface angle is an angle formed between a normal to the sputtered surface (the upper surface of the wafer) and a direction in which the sputtering gas containing Ar⁺ ions falls on the sputtered surface, namely, a downward direction in FIG. 1. For example, the sputtered surface angle is 0° on the upper surface of the wafer and the bottom surface of the recess 4 (FIG. 4) and is 90° on the side wall of the recess.

As obvious from the graph shown in FIG. 2, the upper surface of the wafer, on which the sputtered surface angle is 0°, is sputter-etched to some extent, the side wall of the recess, on which the sputtered surface angle is 90°, is scarcely sputter-etched, and a part around the edge of the open end of the recess, on which the sputtered surface angle is in the range of 40° to 80°, is sputter-etched considerably intensely.

FIG. 3 is a graph showing the relation between bias power and deposition rate at which the film is deposited on the upper surface of the wafer excluding the side walls of the recesses when the plasma-assisted film forming system shown in FIG. 1, namely, the ICP sputtering system, is used. In FIG. 3, bias power is measured on the horizontal axis. The bias power is determined taking the type of the target and the size of the wafer into account. Data shown in FIG. 3 is for a copper target and a 200 mm diameter wafer. When a fixed plasma generating power is supplied, fixed dc power is supplied to the metal target 70 and the bias power is not very high, a film is deposited at a high deposition rate through the attraction of metal ions and the deposition of neutral metal particles. The surface of the wafer starts being sputtered by Ar ions contained in the plasma and accelerated by the bias power upon the increase of the bias power beyond a value of, for example, 50 W (0.16 W/cm²). Thereafter, the sputtering effect of Ar ions increases with the increase of the bias power as shown in FIG. 3. Consequently, the metal film once deposited on the surface of the wafer is etched. The intensity of the etching effect of Ar ions increases with the increase of the bias power.

When the bias power increases such that deposition rate at which the metal ions are attracted and neutral metal atoms are deposited coincides with etch rate at which the metal film deposited on the wafer is etched. Consequently, film deposition and etching cancel each other, and an effective deposition rate drops to zero. Such a condition arises at a point Xl in FIG. 3, where the bias power is 150 W. Values of the bias power and deposition rate shown in FIG. 3 are only examples. When the plasma generating power and the dc power are controlled, the deposition rate varies with the bias power along a curve indicated by a chain line shown in FIG. 3.

General conditions for the operation of a sputtering system of this type are determined so that the curve is in a range A1, in which the bias power is not very high and the deposition rate is high. When the bias power is in this range, the deposition rate is scarcely different from that when the bias power is zero, the deposited film is scarcely etched by the plasma of an inert gas and metal ions are attracted at a maximum rate. Thus a film is deposited at a considerably high deposition rate on the bottom surfaces of the recesses.

A conventional film forming method forms a seed film by continuing a deposition process using bias power near the range A1 for several tens seconds.

The film forming method of the present invention repeats a short film deposition step and a film deposition interrupting step alternately by a number of cycles. The film deposition step uses low bias power proper for depositing the metal film on the upper surface of the wafer and the surfaces of the recesses formed in the surface of the wafer and for avoiding sputtering the metal film once deposited on the upper surface of the wafer and the surfaces of the recesses. Since the short film deposition step is followed by the film deposition interrupting step, the deposited metal film is cooled sufficiently and hence surface diffusion causing formation of overhangs on the metal film does not occur.

The film forming method of the present invention will be described with reference to FIGS. 4 to 6 after understanding the foregoing phenomenon.

Referring to FIG. 1, the stage 34 is lowered, a wafer W is carried through the gate valve 50 into the processing vessel 24 capable of being evacuated, and the wafer W is supported on the support pins 46. Then, the stage 34 is raised to transfer the wafer W from the support pins 46 to the stage 34. The wafer W is attracted to the upper surface of the stage 34 by the electrostatic chuck 34B.

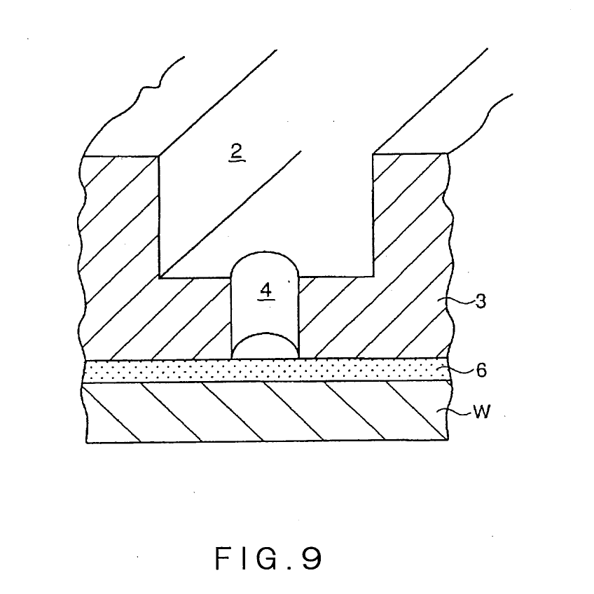

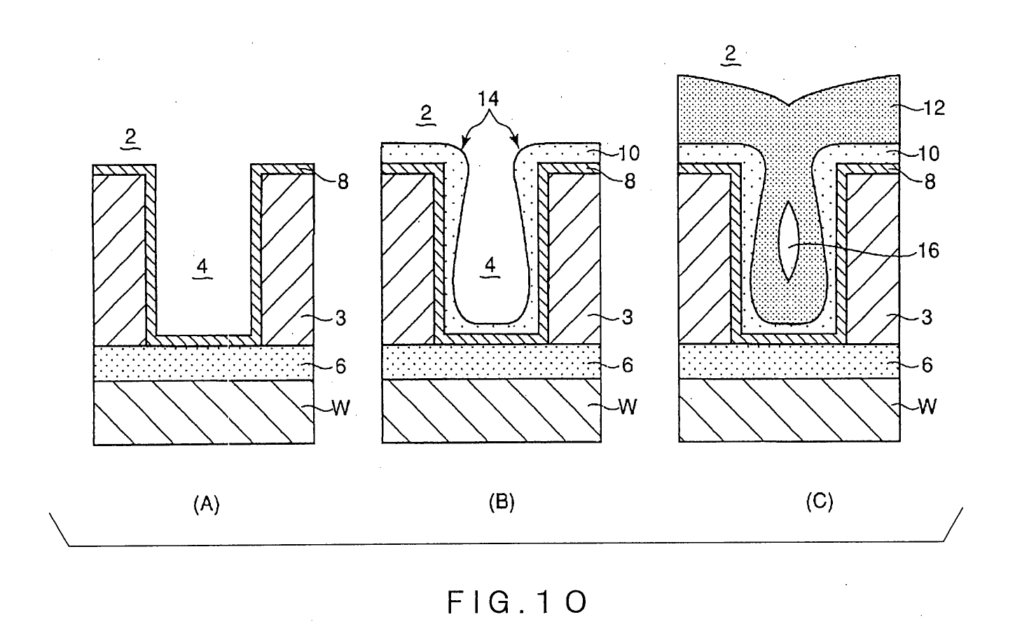

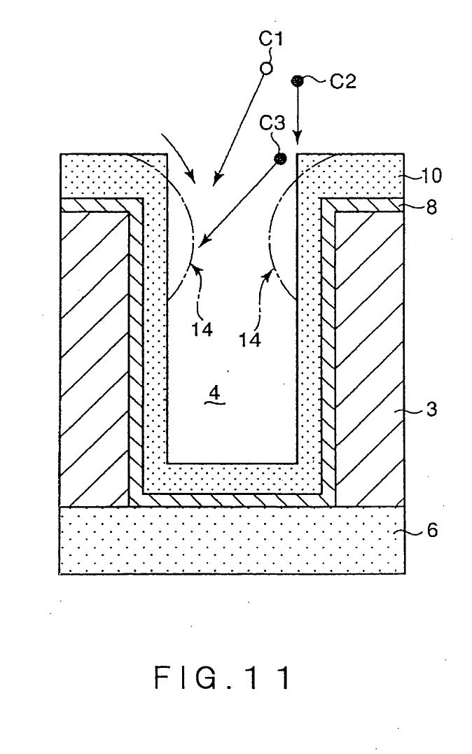

After the wafer W has been mounted on and fixedly attracted to the stage 34, the film deposition process is started. Recesses 2 and 4 like those shown in FIGS. 9 and 10 are formed in the upper surface of the wafer W before the wafer W is carried into the processing vessel 24. The upper recess 2 is a trench. The lower recess 4 formed in the bottom of the recess 2 is a hole extending to a wiring layer 6, such as a via hole or a through hole. Thus the recesses 2 and 4 form a two-step recess. Only the lower recess 4 is shown in FIG. 6.

Step S1 (FIG. 4) is executed to form a barrier layer. The metal target 70 is a tantalum target. The processing vessel 24 is evacuated at a predetermined pressure, plasma generating power is supplied to the induction coil 64 of the plasma generator 62, and predetermined bias power is supplied from the bias power supply 54 to the electrostatic chuck 34B of the stage 34. Predetermined dc power is supplied from the variable dc power supply 72 to the metal target 70 for film deposition. Nitrogen gas for producing TaN is supplied together with a plasma excitation gas, such as Ar gas, through the gas supply port 76 into the processing vessel 24. A TaN film is deposited substantially uniformly on the side and bottom walls of the recess 4 as well as on the upper surface of the wafer W. The bias power is in the range A1 shown in FIG. 3 similarly to the bias power of general film forming conditions. The bias power is on the order of 100 W.

A Ta film forming process is carried out to form a Ta film after the TaN film has been thus formed. Conditions for a Ta film forming process are the same as those for the TaN film forming process, except that the Ta film forming process does not use nitrogen gas. A Ta film is deposited by ionizing the metal target 70 of Ta by a plasma. The bias power is in the range A1 shown in FIG. 3 similarly to the bias power of general film forming conditions. Thus a TaN/Ta barrier layer 8, namely, base film, as shown in FIG. 10(A) is formed in step S4 (FIG. 4). In some cases, the barrier layer 8 is a Ta film.

Then, the wafer W coated with the barrier layer 8 is carried to another plasma-assisted film forming system of the same construction as the plasma-assisted film forming system shown in FIG. 1 without exposing the wafer W to the atmosphere. This plasma-assisted film forming system is provided with a metal target 70 of Cu (copper). The wafer W can be transferred from the plasma-assisted film forming system provided with the metal target 70 of Ta to the plasma-assisted film forming system provided with the metal target 70 of Cu without exposing the wafer W to the atmosphere through a transfer chamber interconnecting those plasma-assisted film forming systems.

The plasma-assisted film forming system is provided with the metal target 70 of Cu to form a seed film of Cu. A processing vessel 24 is evacuated at a predetermined pressure, plasma generating power is supplied to an induction coil 64 included in a plasma generator 62, and predetermined bias power is supplied from a bias power supply 54 to an electrostatic chuck 34B included in a stage 34. Predetermined dc power is supplied from a variable dc power supply 72 to the metal target 70 for film deposition. A plasma excitation gas, such as Ar gas, is supplied through a gas supply port 76 into the processing vessel 24.

As shown in FIGS. 4 and 5, this film forming method of the present invention repeats a film deposition step S2 of depositing a metal film of Cu and a film deposition interrupting step S3 of interrupting the deposition of the metal film to cool the deposited metal film alternately by a predetermined number of cycles while the response to a query made in step S4 is negative. The response to a query made in step S4 is affirmative after the film deposition step and the film deposition interrupting step have been repeated alternately by the predetermined number of cycles. When the response to the query made in step S4 is affirmative, the film forming process is ended.

FIG. 5 shows a film forming process in which the film deposition step and the film deposition interrupting step are repeated by four cycles. A seed film 92 of four metal layers 90A, 90B, 90C and 90D deposited by the four cycles of the film deposition step and the film deposition interrupting step, respectively, as shown in FIG. 6 is formed. The high-frequency power supply 66 (FIG. 5(A)) for plasma generation, the dc power supply 72 (FIG. 5(B)) for the metal target and the bias power supply 54 (FIG. 5(C)) are turned on in the film deposition step to deposit a metal film of Cu.

The high-frequency power supply 66 (FIG. 5(A)) for plasma generation, the dc power supply 72 (FIG. 5(B)) for the metal target and the bias power supply 54 (FIG. 5(C)) are turned off in the film deposition interrupting step. Consequently, the production of metal ions and film deposition are interrupted.

At least both the high-frequency power source 66 for plasma generation and the dc power supply 72 for the metal. target are turned off to interrupt metal ion production and plasma generation in the film deposition interrupting step.

As shown in FIG. 5(E), a coolant of a temperature, for example, between −20° C. and −50° C. is circulated through the coolant circulating passage 42 through out the film deposition step and the film deposition interrupting step to cool the wafer W, so that surface diffusion does not occur in the deposited metal films 90A to 90D through out the film deposition step and the film deposition interrupting step.

Setting of the bias power for the film deposition step will be explained. As mentioned above, the low bias power in a range A2 shown in FIG. 3 is used for the film deposition step so that the metal film is deposited on the upper surface of the wafer and the surfaces of the recess and the deposited metal film is not etched by the sputtering effect of the ions contained in the plasma.

The upper limit bias power of the range A2 for, for example, a 300 mm diameter wafer is on the order of 200 W (0.3 W/cm²). A bias power higher than the upper limit bias power increases attraction acting on Ar ions excessively. Consequently, the metal films 90A to 90D deposited on the wafer W are sputtered and overhangs tend to start forming around the edges of the recess 4. There is not lower limit bias power; the bias power may be 0 W.

In the film deposition step, the interior of the processing vessel 24 is set at a pressure not lower than a predetermined pressure of, for example, 50 mTorr (6.7 Pa) to ionize Cu at an ionization rate of 80% or above. When the ionization rate is 80% or above, the ratio of directional metal ions is large and the ratio of nondirectional neutral particles is small. Consequently, metal ions are dominant particles contributing to film deposition, neutral particles falling on the edges of the open end of the recess 4 from all directions decreases relatively and hence formation of overhangs on the edges of the open end of the recess 4 can be suppressed. If the ionization rate is below 80%, the degree of contribution of neutral particles to film formation increases and formation of overhangs is promoted undesirably.

Although dependent on process conditions, an ionization ratio of 80% or above can be achieved by setting the process pressure at least 50 mTorr or above, preferably, 90 mTorr or above. If the process pressure is excessively high, the deposition rate decreases sharply. The upper limit of the process pressure is on the order of 100 mTorr. The wafer W is cooled continuously through out the film deposition step and the film deposition interrupting step by the coolant circulated through the coolant circulating passage 42, namely, the cooling means. The aggregation of deposited metal particles due to the excessive heating of the wafer W can be avoided in the film deposition step. The wafer can be sufficiently cooled during the film deposition interrupting step because Ar ions do not impart energy to the wafer. Thus surface diffusion in the deposited Cu film can be prevented and hence formation of overhangs can be suppressed.

Thus overhang suppressing actions are effected cooperatively and the formation of overhangs of the seed film 92 in the vicinity of the open end of the recess 4 can be substantially surely prevented.

Numerical examples will be explained. The present invention is effective in depositing a film on the wafer provided with the recess 4 having a width or a diameter of 150 nm or below, particularly, 100 nm or below. The period T1 of the film deposition step is between 2 and 10 sec, for example, on the order of 5.5 s. The period T2 of the film deposition interrupting step is between 5 and 20 sec, for example, on the order of 10 sec. The conventional film deposition method forms a seed film by a continuous film deposition step (continuous sputtering step) that is continued for 22 sec.

The thickness H1 of the seed film 92 shown in FIG. 6 is between 40 and 100 nm, for example, on the order of 60 nm. The thickness H2 of the seed film 92 deposited on the side wall of the recess 4 is about 15% to about 20% of the thickness H1. The thickness H3 of the seed film 92 deposited on the bottom of the recess 4 is about 80% to about 90% of the thickness H1.

The period of one cycle of the film deposition step for forming the metal film 90 is not longer than 10 sec. If this period is longer than 10 sec, aggregation occurs in the deposited metal film 90, causing formation of overhangs.

### Evaluation

Seed films were formed by the film forming method (intermittent sputtering method) of the present invention and by a conventional film forming method (a continuous sputtering method), and the seed films were examined. Results of examination will be described.

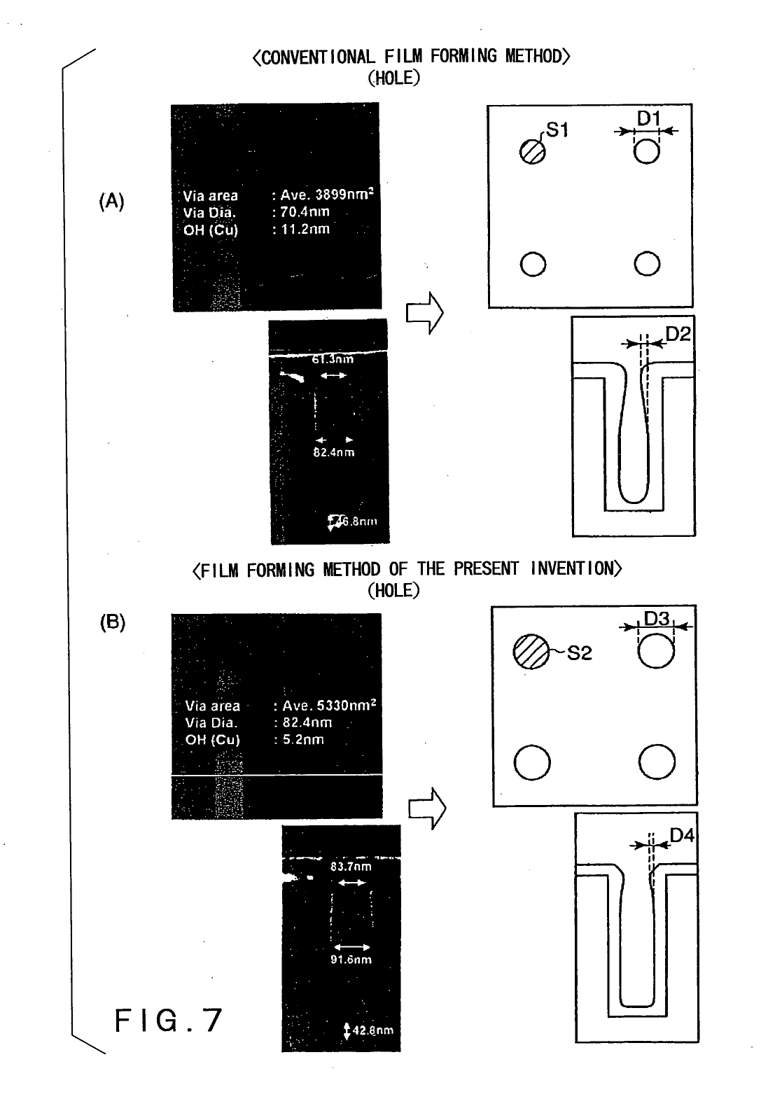

FIGS. 7(A) and 7(B) are microphotographs of holes in which seed films were deposited by a conventional film forming method (a continuous sputtering method) and the film forming method (intermittent sputtering method) of the present invention, respectively, taken by an electron photomicroscope. In FIGS. 7(A) and 7(B), typical pattern diagrams of parts around holes are shown on the right-hand side of the microphotographs for reference.

A first sample processed by the conventional film forming method is shown in a plan view and a sectional view in FIG. 7(A), and a second sample processed by the film forming method of the present invention is shown in a plan view and a sectional view in FIG. 7(B). The diameters of the recess, namely, via holes, are 110 nm. Dimensions of parts of the samples are indicated in the microphotographs. In the microphotographs, indicated at “OH” are dimensions of overhangs.

Process conditions for the conventional film forming method and the film forming method of the present invention were the same. Process conditions were as follows.

Process pressure: 90 mTorr, plasma generating power of the high-frequency power supply 66: 16 kW, discharging power of the dc power supply: 16 kW, bias power: 35 W, film deposition time of the film forming method of the present invention: 5.5 sec×4 cycles, and film deposition time of the conventional film forming method (continuous sputtering method): 22 sec.

In the first sample shown in FIG. 7(A), the mean area S1 of a via area was 3899 nm², the diameter D1 of the via hole was 70.4 nm, and thickness D2 of the overhang was 11.2 nm. On the other hand, in the second sample shown in FIG. 7(B), the mean area S2 of a via area was 5330 nm², the diameter D3 of the via hole was 82.4 nm, and thickness D4 of the overhang was 5.2 mm.

Whereas the thickness of the overhang in the first sample was 11.2 nm, that of the overhang in the second sample was as small as 5.2 nm. The big difference in the thickness of the overhang between the first and the second sample proved that the film forming method of the present invention could effectively suppress the formation of overhangs.

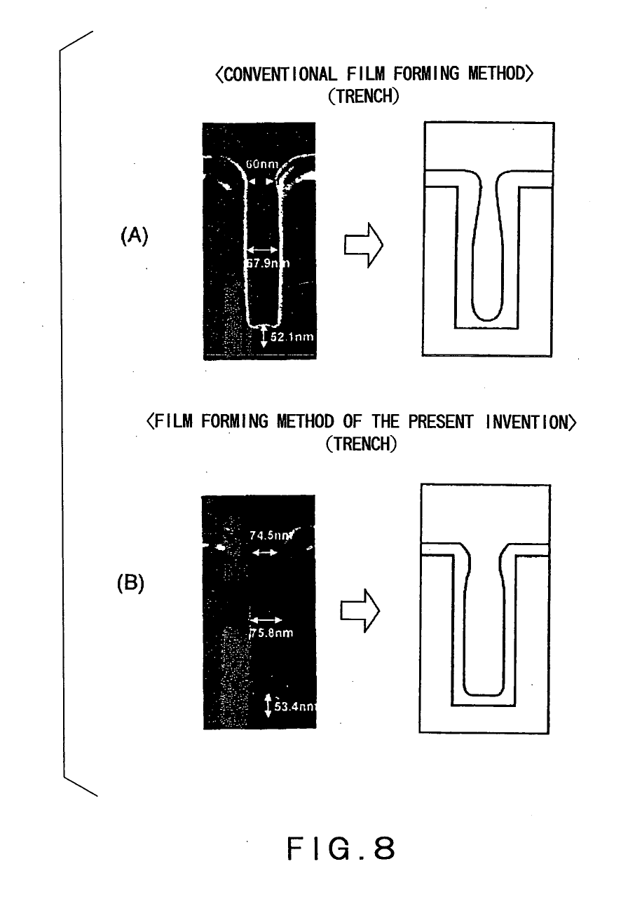

Seed films were deposited in trenches having a width of 110 nm formed in wafers by film forming methods similar to the foregoing film forming methods under the same process conditions. FIGS. 8(A) and 8(B) are microphotographs of trenches in which seed films were deposited by a conventional film forming method (a continuous sputtering method) and the film forming method (intermittent sputtering method) of the present invention, respectively, taken by an electron photomicroscope. In FIGS. 8(A) and 8(B), typical pattern diagrams of parts around the trenches are shown on the right-hand side of the microphotographs for reference.

A first sample processed by the conventional film forming method is shown in a sectional view in FIG. 8(A), and a second sample processed by the film forming method of the present invention is shown in a sectional view in FIG. 8(B). Whereas a gap between the opposite overhangs was 60 nm in the first sample shown in FIG. 8(A), a gap between the opposite overhangs was 74.5 nm in the second sample. Thus it was proved that the film forming method of the present invention could effectively suppress the formation of overhangs.

Although the film forming method embodying the present invention has been described as applied to forming the metal film 90 of Cu or a Cu alloy, the present invention is applicable to forming metal films of, for example, tungsten (W), tantalum (Ta), ruthenium (Ru) and alloys of those metals.

The frequency of each high-frequency power supply is not limited to 13.56 MHz and may be any suitable frequency, such as 27.0 MHz. The inert gas for generating a plasma is not limited to Ar gas and may any suitable inert gas, such as He or Ne gas.

Although the invention has been described as applied to forming a film on the semiconductor wafer by way of example, the present invention is applicable to forming a film on an LCD substrate, a glass substrate, a ceramic substrate and the like.

1. A seed film forming method of depositing a seed film for plating comprising the steps of: producing metal ions by ionizing a metal target with a plasma in a processing vessel that can be evacuated; and depositing a metal film on a surface provided with recesses of a workpiece mounted on a stage placed in the processing vessel by supplying bias power to the workpiece to attract the metal ions to the workpiece;
wherein a film deposition step of depositing the metal film by using the bias power determined so that the metal film deposited on the surface of the workpiece may not be sputtered, and a film deposition interrupting step of interrupting the deposition of the metal film by stopping producing the metal ions are repeated alternately by a number of cycles.

2. The seed film forming method according to claim 1, wherein the film deposition step sets the interior of the processing vessel at a pressure not lower than a predetermined pressure to produce the metal ions at an ionization rate not lower than a predetermined ionization rate.

3. The seed film forming method according to claim 2, wherein the predetermined ionization rate is 80%.

4. The seed film forming method according to claim 2, wherein the predetermined pressure is 50 mTorr.

5. The seed film forming method according to claim 1, wherein the film deposition interrupting step stops the supply of plasma generating power for generating the plasma and the supply of discharging power supplied to the target.

6. The seed film forming method according to claim 1, wherein the film deposition interrupting step stops the supply of the bias power.

7. The seed film forming method according to claim 1, wherein the workpiece is cooled throughout the film deposition step and the film deposition interrupting step.

8. The seed film forming method according to claim 1, wherein the duration of one cycle of the film deposition step is 10 sec or below.

9. The seed film forming method according to claim 1, wherein the seed film has an overall thickness of 100 nm or below.

10. The film forming method according to claim 1, wherein the bias power is 0.3 W/cm² or below.

11. The seed film forming method according to claim 1, wherein the recess has a width or a diameter of 150 nm or below.

12. The seed film forming method according to claim 1, wherein the metal film is formed of copper, ruthenium (Ru), a copper alloy or a ruthenium alloy.

13. A plasma-assisted film forming system for depositing a metal film as a seed film for plating on the surface of a workpiece and in recesses in the workpiece by attracting metal ions by the agency of bias power, said plasma-assisted film forming system comprising:
a processing vessel capable of being evacuated;
a stage for supporting thereon a workpiece having a surface provided with recesses;
a gas supply means for supplying predetermined gases into the processing vessel;
a plasma generator for generating a plasma in the processing vessel;
a metal target placed in the processing vessel so as to be ionized by the plasma;
a dc power supply for supplying discharge power to the metal target;
a bias power supply for supplying bias power to the stage; and
a system controller for controlling operations of the plasma-assisted film forming system;
wherein the system controller executes control operations so that a film deposition step using the bias power adjusted such that the metal film deposited on the surface of the workpiece is not sputtered, and a film deposition interrupting step of interrupting the deposition of the metal film by stopping producing metal ions are repeated alternately by a number of cycles.

14. The plasma-assisted film forming system according to claim 13, wherein the stage is provided with a cooling means for cooling the workpiece.

15. The plasma-assisted film forming system according to claim 13, wherein the stage is provided in its surface with gas grooves through which a heat-transfer gas flows.

16. A storage medium storing a control program for controlling film deposition operations of a plasma-assisted film forming system for depositing a metal film as a seed film for plating on the surface of a workpiece and in recesses in the workpiece by attracting metal ions by the agency of bias power, said plasma-assisted film forming system including
a processing vessel capable of being evacuated,
a stage for supporting thereon a workpiece having a surface provided with recesses,
a gas supply means for supplying predetermined gases into the processing vessel,
a plasma generator for generating a plasma in the processing vessel,
a metal target placed in the processing vessel so as to be ionized by the plasma,
a dc power supply for supplying discharge power to the metal target,
a bias power supply for supplying bias power to the stage, and
a system controller for executing the control program, such that a film deposition step using the bias power adjusted so that the metal film deposited on the surface of the workpiece may not be sputtered, and a film deposition interrupting step of interrupting the deposition of the metal film by stopping producing the metal ions are repeated alternately by a number of cycles.
